(19) United States
(12) Patent Application Publication
(10) Pub. No.: US 2019/0174611 A1
(43) Pub. Date: Jun. 6, 2019

(54) LIGHT SWITCH AS TOUCHLESS CONTROLLER

(71) Applicant: Javier Senas, Regensburg (DE)

(72) Inventor: Javier Senas, Regensburg (DE)

(21) Appl. No.: 15/990,789

(22) Filed: May 28, 2018

(30) Foreign Application Priority Data
Dec. 4, 2017 (DE) 10 2017 128 701.9

(51) Int. Cl. H05B 37/02; G06F 3/01; H03K 17/96; H05B 33/08

(52) U.S. Cl. CPC H05B 37/0272; H05B 33/0845; H03K 17/96; G06F 3/017

(57) ABSTRACT

The invention is a wall-mounted light switch that includes a sensor module configured to detect a touchless gestures and a controlling module configured to control the light source in response to the detected first gesture.

### CROSS-REFERENCE TO RELATED APPLICATIONS

The present application claims priority to German patent application number 10 2017 128 701.9, entitled, LIGHT SWITCH, filed in the European Patent Office on Dec. 4, 2017. That application is fully incorporated by reference herein.

### FIELD OF INVENTION

The invention relates to a light switch for wall mounting.

### BACKGROUND

Typically, light switches are equipped with buttons or touch sensors and usually have only two states, which is not versatile. A need exists for more versatile light switches.

### SUMMARY

The object of the invention is to contribute to a more versatile light switch. This object is achieved by one embodiment of the invention, which is a wall-mounted light switch including a sensor module and at least one controlling module, wherein the sensor module is configured to detect a first gesture of a given first set of touchless gestures of a user, and the controlling module is configured to control an electrical device different from the light source according to the detected first gesture.

In another embodiment of the invention, a wall-mounted light switch is provided that includes a sensor module, a first controlling module, and a second controlling module, wherein the sensor module comprises infrared, capacitive, radar, Doppler effect, sonar, hall effect, optical, image, inductive, magnetic and ultrasonic-based sensor and the sensor module is configured to detect a first gesture of a given first set of touchless gestures of a user and a second gesture of a given second set of touchless gestures of a user and a second controlling module. The first controlling module is configured to control a light source according to the detected first gesture and includes a wireless communication module adapted to control the light source wirelessly. The second controlling module is configured to control one or more of a blind, a shade, a door, a marquise, a water valve, a heating, an air conditioning according to the detected second gesture, and the second controlling module includes a communication module configured to control the electrical device wirelessly.

### BRIEF DESCRIPTION OF THE DRAWINGS

FIG. 1 a plan view of one embodiment of the light switch of the invention.

FIG. 2 is an exploded view of the light switch of FIG. 1.

### DETAILED DESCRIPTION

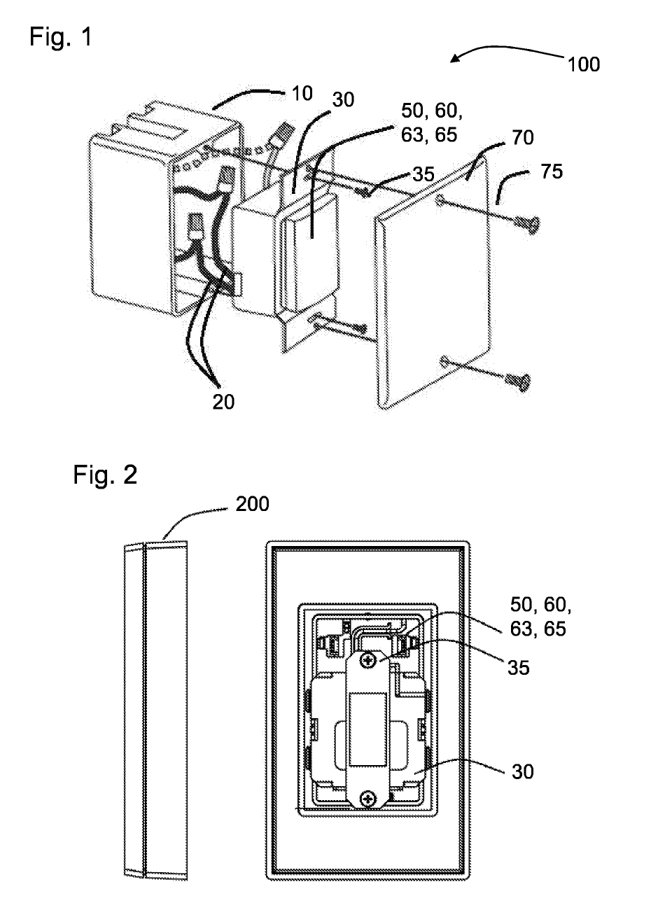

The invention is best understood by referring to the various Figures. FIG. 1 shows one embodiment of light switch 100. Light switch 100 comprises wall housing to and electrical power wiring 20, and light switch circuitry housing 30. Light switch 100 further comprises a sensor module 50, and a first controlling module 60. In alternative embodiments of the invention, light switch 100 comprises second controlling module 63 and/or third controlling module 65. The shown place of sensor module 50 and controlling modules 60, 63, 65 inside light switch 100 is optional and the invention is not limited to any particular placement of these elements.

Light switch circuitry housing 30 can be fixed to the wall housing by means of screws 35 or any other potential fixing means.

Light switch 100 further comprises light switch cover 70, which can be fixed to light switch circuitry housing 30 by means of screws 75, or any other potential fixing means.

By means of a touchless gesture detection, light switch 100 becomes more versatile, since the possible amount of states can be larger. For example, the gestures correspond to movements in three axes: from left to right and vice versa, from top to bottom and vice versa, and from far to close and vice versa. Since the gesture detection is touchless, light switch 100 and its surrounding does not get dirty since there is no need to touch the light switch.

According to one embodiment, first controlling module 60 comprises a wireless communication module (not shown) to control the light source wirelessly. By a wireless control, light switch 100 does not need to be directly connected to the light source and thus can be arranged more versatile.

According to a further embodiment, sensor module 50 is further configured to detect a second gesture of a given second set of touchless gestures of a user and light switch 100 further comprises a second controlling module 63 configured to control an electrical device different from the light source according to the detected second gesture.

Since the possible amount of states can be larger, the light switch can also be used for multiple devices. For example, the gestures in each axis correspond to one device: movement from left to right and vice versa control a first device, movement from top to bottom and vice versa control a second device, movement from far to close and vice versa control a third device.

According to a further embodiment, second controlling module 63 comprises a communication module to control the electrical device wirelessly.

By a wireless control, light switch 100 does not need to be directly connected to the electrical device and thus can be arranged more versatile.

According to further embodiments, the electrical device is one or more of the following devices: a blind, a shade, a door, a marquise, a water valve, a heating, and an air conditioning.

According to further embodiments, the sensor module comprises at least one of a touchless sensor and/or a proximity sensor.

According to further embodiments, the touchless sensor and/or proximity sensor is an infrared-, capacitive-, radar-, Doppler effect-, sonar-, hall effect-, optical-, image-, inductive-, magnetic and/or ultrasonic-based sensor.

According to further embodiments, the controlling of the light source comprises turning on, off and/or adjusting a brightness of the light source.

FIG. 2 illustrates the light switch circuitry housing 30 in more detail. Light switch circuitry housing 30 can cover circuitry of light switch 100 partly or totally.

The shown place of the sensor module 500 and the controlling modules 6o, 63, 65 inside the light switch 100 is optional and not limited to it.

FIG. 2 further shows the light switch in a profile view 200. The light switch circuitry housing 30 can be fixed to the light switch circuitry by means of screws 35 or any other potential fixing means.

The sensor module 50 is configured to detect a first gesture of a given first set of touchless gestures of a user.

The first controlling module 60 is configured to control a light source according to the detected first gesture.

If the light switch 100 comprises a second and/or third and or further controlling module 63, 65, the sensor module 50 is further configured to detect a second gesture of a given second set of touchless gestures of a user and/or configured to detect a third gesture of a given third set of touchless gestures of a user and/or configured to detect a further gesture of a given third set of touchless gestures of a user.

For example, the gestures in each axis correspond to one electrical device: movement from left to right and vice versa control a first device, movement from top to bottom and vice versa control a second device, movement from far to close and vice versa control a third device.

The controlling modules 60, 63, 65 may each comprise a wireless communication module to control the light source or the corresponding devices wirelessly.

In various embodiments of the invention, the electrical device is one or more of the following devices: a blind, a shade, a door, a marquise, a water valve, a heating, an air conditioning.

In various embodiments of the invention, sensor module 50 comprises, for example, a touchless sensor and/or a proximity sensor.

The touchless sensor and/or proximity sensor is, for example, an infrared-, capacitive-, radar-, Doppler effect-, sonar-, hall effect-, optical-, image-, inductive-, magnetic- and/or ultrasonic-based sensor.

The controlling the light source comprises, for example, turning on, off and/or adjusting a brightness of the light source.

By means of the above described light switch 100 the light switch 100 can be used as touchless controller and replace classical buttons with just two states (on, off) to avoid such light switch and its surrounding to get dirty while increasing state options by using different gestures in the sensor modules target such as movements, but not limited to, from left to right and vice versa, from top to bottom and vice versa, from far to close and vice versa and in general, different positions and movements of the target.

According to a further embodiment, the light switch comprises an image sensor to detect different positions of the target based on augmented reality.

According to a further embodiment, the light switch comprises a radar sensor to detect any kind of movement of the target.

Depending on the identified gesture, lights could turn on, off or the luminosity could be adjusted.

Optionally, the light switch 100 may also comprise a built-in dimmer and/or be programmed to track activity of such light sources providing with its power consumption monitoring.

Optionally, the light switch may also comprise a display and/or laser to create an augmented reality signal.

Optionally, the light switch 100 may also be adapted to permit a user to command and control additionally to the lights at least one wired or wireless device such as, but not limited to, blinds, shades, doors, marquises, water valves, heating, air conditioning, etc. This will reduce the number of switches, controls and wiring significantly.

For example, if the sensor module 50 detects a gesture movement from far to close or vice versa one of the controlling modules 60, 63, 65 increases or decreases lights intensity. If the sensor module 50 detects a gesture movement from up to down or vice versa one of the controlling modules 60, 63, 65 rolls down or rolls up the blinds and/or shades. If the sensor module 50 detects a gesture movement from up to down or vice versa one of the controlling modules 60, 63, 65 opens or closes a door and/or a marquise.

For example, if the sensor module 50 detects a gesture movement from left to right or vice versa one of the controlling modules 60, 63, 65 opens or closes a water valve and/or turns on or off the heating and/or air conditioning.

For example, if the sensor module 50 detects a gesture movement from left to right or vice versa one of the controlling modules 6o, 63, 65 opens or closes a water valve and/or turns on or off the heating and/or air conditioning.

For example, if an augmented reality signal is generated and it is displaying images and/or icons of different external devices, such as but not limited to door, marquise, radiator, blinds or shades, the proximity sensor target can easily be placed in a position where, the image sensor of the light switch will identify such position and control accordingly the external device.

Further, same gestures can be in the given first set and/or second set and/or third set and/or further set of touchless gestures so that multiple devices could be controlled simultaneous with the same gesture.

Alternatively, the given first set and/or second set and/or third set and/or further set of touchless gestures all comprise different gestures, so that one gesture always correspond to only one device. Further, a sequence of gestures could be read by the sensor module 50 to control the devices sequentially.

The light switch could be further used as an alarm system. For example, if a non-identified person or a non-identified gesture is detected by the sensor module 50, the light switch 100 might comprise a communications module which enables connection to the Internet and the light switch could notify the presence of the non-identified person or a non-identified gesture.

The above description is illustrative and not restrictive. Many variations of the invention will become apparent to those of skill in the art upon review of this disclosure. The scope of the invention should, therefore, be determined not with reference to the above description, but instead should be determined with reference to the appended claims along with their full scope of equivalents.

While the present invention has been described in connection with a series of preferred embodiment, these descriptions are not intended to limit the scope of the invention to the particular forms set forth herein. It will be further understood that the methods of the invention are not necessarily limited to the discrete steps or the order of the steps described. To the contrary, the present descriptions are intended to cover such alternatives, modifications, and equivalents as may be included within the spirit and scope of the invention as defined by the appended claims and otherwise appreciated by one of ordinary skill in the art.

What is claimed:

1. A wall-mounted light switch comprising a sensor module and at least one controlling module, wherein the sensor module is configured to detect a first gesture of a given first set of touchless gestures of a user, and wherein the at least one controlling module is configured to control an electrical device different from the light source according to the detected first gesture.

2. The light switch according to claim 1, wherein the controlling module comprises a wireless communication module adapted to control the light source wirelessly.

3. The light switch according to claim 1, wherein the sensor module is further configured to detect a second gesture of a given second set of touchless gestures of a user and a second controlling module, wherein the second controlling module is configured to control a light source according to the detected second gesture.

4. The light switch according to claim 2, wherein the sensor module is further configured to detect a second gesture of a given second set of touchless gestures of a user and a second controlling module, wherein the second controlling module is configured to control a light source according to the detected second gesture.

5. The light switch according to claim 3, wherein the second controlling module comprises a communication module configured to control the electrical device wirelessly.

6. The light switch according to claim 4, wherein the second controlling module comprises a communication module configured to control the electrical device wirelessly.

7. The light switch according to claim 1, wherein the electrical device is one or more of the following devices: a blind, a shade, a door, a marquise, a water valve, a heating, an air conditioning.

8. The light switch according to claim 1, wherein the sensor module comprises at least one of a touchless sensor and a proximity sensor.

9. The light switch according to claim 2, wherein the sensor module comprises at least one of a touchless sensor and a proximity sensor.

10. The light switch according to claim 7, wherein the sensor module comprises at least one of a touchless sensor and a proximity sensor.

11. The light switch according to claim 3, wherein the sensor module comprises at least one of a touchless sensor and a proximity sensor.

12. The light switch according to claim 8, wherein the touchless sensor is at least one of an infrared, capacitive, radar, Doppler effect, sonar, hall effect, optical, image, inductive, magnetic and ultrasonic-based sensor.

13. The light switch according to claim 8, wherein the proximity sensor is at least one of an infrared, capacitive, radar, Doppler effect, sonar, hall effect, optical, image, inductive, magnetic and ultrasonic-based sensor.

14. The light switch according to claim 1, further comprising a wall housing, electrical power wiring, and light switch circuitry housing.

15. The light switch according to claim 1, wherein the light switch is configured to be programmable.

16. The light switch according to claim 1, further comprising a dimmer.

17. The light switch according to claim 1, further comprising a means for creating an augmented reality signal.

18. The light switch according to claim 1, further comprising communications module which enables connection to the Internet.

19. A wall-mounted light switch comprising a sensor module and at least one controlling module, wherein the sensor module is configured to detect a first gesture of a given first set of touchless gestures of a user, and wherein the at least one controlling module is configured to control a light source according to the detected first gesture, wherein the controlling module comprises a wireless communication module adapted to control the light source wirelessly, wherein the sensor module is further configured to detect a second gesture of a given second set of touchless gestures of a user and a second controlling module, wherein the second controlling module is configured to control an electrical device different from the light source according to the detected second gesture, wherein the second controlling module comprises a communication module configured to control the electrical device wirelessly, and wherein the sensor module comprises at least one of a touchless sensor and a proximity sensor.

20. A wall-mounted light switch comprising:
a sensor module, a first controlling module, and a second controlling module,
wherein the sensor module comprises infrared, capacitive, radar, Doppler effect, sonar, hall effect, optical, image, inductive, magnetic and ultrasonic-based sensor and the sensor module is configured to detect a first gesture of a given first set of touchless gestures of a user and a second gesture of a given second set of touchless gestures of a user and a second controlling module,
wherein the first controlling module is configured to control a light source according to the detected first gesture, and comprises a wireless communication module adapted to control the light source wirelessly,
wherein the second controlling module is configured to control one or more of a blind, a shade, a door, a marquise, a water valve, a heating, an air conditioning according to the detected second gesture, and the second controlling module comprises a communication module configured to control the electrical device wirelessly.
